(19) United States
(12) Patent Application Publication
(10) Pub. No.: US 2022/0320368 A1
(43) Pub. Date: Oct. 6, 2022

(54) MINI-LIGHT EMITTING DIODE LIGHT BOARD, BACKLIGHT MODULE, AND PREPARATION METHOD THEREOF

(71) Applicant: TCL CHINA STAR OPTOELECTRONICS TECHNOLOGY CO., LTD., Shenzhen, Guangdong (CN)

(72) Inventor: Daobing HU, Shenzhen, Guangdong (CN)

(73) Assignee: TCL CHINA STAR OPTOELECTRONICS TECHNOLOGY CO., LTD., Shenzhen, Guangdong (CN)

(21) Appl. No.: 16/973,790

(22) PCT Filed: Nov. 30, 2020
(86) PCT No.: PCT/CN2020/132848

§ 371 Date: Dec. 10, 2020

(30) Foreign Application Priority Data
Oct. 15, 2020 (CN) 202011103751.8

(51) Int. Cl. H01L 33/10; H01L 33/62; G02F 1/13357; H01L 33/00

(52) U.S. Cl. CPC H01L 33/10; H01L 33/62; G02F 1/133603; G02F 1/133605; H01L 33/005; H01L 2933/0066

(57) ABSTRACT

A mini-light emitting diode light board, a backlight module, and a preparation method thereof are provided. The mini-light emitting diode light board mainly comprises: a substrate, a first reflective layer, a circuit layer, and a plurality of mini-light emitting diodes laminated in sequence, wherein the plurality of mini-light emitting diodes are arranged on the circuit layer at intervals, and the mini-light emitting diode light board can be configured as a backlight source of the backlight module, which has advantages of improving light utilization rate and saving energy consumption.

### BACKGROUND OF INVENTION

### Field of Invention

The present application relates to the field of display technology, in particular to a mini-light emitting diode light board, a backlight module, and a preparation method thereof.

### Description of Prior Art

Liquid crystal displays are mainstream products in display panel market. Backlight module is a key component of the liquid crystal displays, and is used to provide sufficient and uniformly distributed light sources so that the liquid crystal displays can display pictures. A traditional backlight module usually comprises a backlight source, a light guide plate, an optical film, a plastic frame, and other components. Depending on a distribution of the light sources, the traditional backlight module is divided into two types: an edge-type backlight module and a direct-type backlight module.

When the traditional backlight module is turned on, since all the backlight sources on it are turned on, an area on a liquid crystal display panel that does not need to display is also illuminated by the backlight, so that contrast between a bright state and a dark state is low. Mini-light emitting diode (mini-LED) backlight modules have characteristics of good display performance, low power consumption, high brightness, etc., and when the mini-LED backlight modules are turned on, not all of the mini-LEDs are turned on. Rather, mini-LEDs that matched the display screen are turned on, so that the area that does not need to be displayed is completely dark, thereby achieving high contrast.

### SUMMARY OF INVENTION

An existing mini-LED backlight module comprises a mini-LED light board. As shown in FIG. 1, the mini-LED light board generally comprises: a glass substrate 100; a plurality of mini-LEDs 200 arranged at intervals on the glass substrate 100; and a white oil reflective layer 300 laminated on the glass substrate 100, the white oil reflective layer 300 is provided with a white oil opening at the position of each mini-LED 200, so that each of the mini-LEDs 200 is exposed on the white oil reflective layer 300. The white oil reflection layer 300 is used to enhance the reflection effect of the glass substrate 100 on a light, improve the utilization rate of the light, and prevent the shortcomings of low reflectivity and high light loss rate in an area where mini-LED 200 is not provided on the glass substrate 100. However, due to the hole-opening process, it is impossible to ensure that the white oil opening is fully compatible with the mini-LED 200, that is, there is a gap 400 between the edge of the white oil opening and the edge of the mini-LED 200. Light will leak from the gap 400, thereby reducing the utilization of light.

In view of the shortcomings of the prior art, the main purpose of the application is to provide a mini-LED light board, backlight module and preparation method thereof, so as to improve the problem of the large light loss rate and light utilization of the existing mini-LED backlight module.

In order to achieve the aforementioned purpose of the application, in a first aspect, the application provides a miniature light-emitting diode lamp panel, comprising:

a substrate;

a first reflective layer laminated on a surface of the substrate;

a circuit layer laminated on a surface of the first reflective layer facing away from the substrate, and a plurality of electrical connection positions are provided on the circuit layer; and

a plurality of mini-light emitting diodes electrically connected to each of the electrical connection positions, respectively, and the plurality of mini-light emitting diodes are arranged at intervals.

Further, the first reflective layer is a distributed Bragg reflector structure.

As a preferred embodiment of the present application, the first reflective layer is composed of a first silicon nitride layer, a silicon oxide layer and a second silicon nitride layer stacked in sequence.

As another preferred embodiment of the present application, the first reflective layer is composed of a first silicon nitride layer, an amorphous silicon layer and a second silicon nitride layer stacked in sequence.

Further, the circuit layer is at least one of a printed circuit board, a BT board, an aluminum substrate, or a flexible circuit board.

In a second aspect, the present application provides a backlight module, comprising:

a mini-light emitting diode light board, the mini-light emitting diode light board comprising: a substrate, a first reflective layer, a circuit layer, and a plurality of mini-light emitting diodes; the first reflective layer is laminated on a surface of the substrate, the circuit layer is laminated on a surface of the first reflective layer facing away from the substrate, a plurality of electrical connection positions are provided on the circuit layer, the plurality of mini-light emitting diodes are electrically connected to each of the electrical connection positions, respectively, and the plurality of mini-light emitting diodes are arranged at intervals; and

a second reflective layer laminated on a surface of the mini-light emitting diode light board, and a plurality of spaced openings are provided on the second reflective layer to expose each of the mini-light emitting diodes.

Further, a material of the second reflective layer is white ink with reflective effect.

Further, the backlight module further comprises: a protective layer covering each of the mini-light emitting diodes and the second reflective layer.

Further, a material of the protective layer is silica gel or epoxy resin.

Further, the backlight module further comprises: an optical film laminated on a surface of the second reflective layer facing away from the mini-light emitting diode light board.

Further, the optical film comprises one or more of a prism film, a quantum dot film, a diffusion film, and a reflective polarizer.

Further, the backlight module further comprises: an outer frame, the outer frame is composed of a metal back plate and four metal retaining walls, the metal back plate, the mini-light emitting diode light board and the second reflective layer are laminated and arranged in sequence, and each of the metal retaining walls is arranged around the mini-light emitting diode light board and the second reflective layer.

Further, the backlight module further comprises: a plastic frame arranged around the mini-light emitting diode light board and the second reflective layer, and each of the metal retaining walls is respectively arranged on a periphery of the plastic frame.

Further, the backlight module further comprises: a double-sided adhesive layer disposed between the metal back plate and the mini-light emitting diode light board.

Further, the backlight module further comprises: a light-shielding layer disposed on a top of each of the metal retaining walls.

In a third aspect, the present application provides a method for manufacturing a backlight module, comprising following blocks of:

preparing a mini-light emitting diode light board, wherein the mini-light emitting diode light board comprises: a substrate; a first reflective layer laminated on a surface of the substrate; a circuit layer laminated on a surface of the first reflective layer facing away from the substrate; and a plurality of electrical connection positions provided on the circuit layer; and a plurality of mini-light emitting diodes are electrically connected to each of the electrical connection positions, respectively, and the plurality of mini-light emitting diodes are arranged at intervals, and

printing a second reflective layer on a surface of the mini-light emitting diode light board, and the second reflective layer is respectively provided with an opening at a position of each of the mini-light emitting diodes, so that each of the mini-light emitting diodes is exposed.

Further, in the block of printing the second reflective layer on the surface of the mini-light emitting diode light board, the printing is a jet printing process or a silk screen process.

Further, the block of preparing the mini-light emitting diode light board comprises following blocks of:

providing the substrate, and depositing the first reflective layer on the surface of the substrate to form an entire surface;

preparing the circuit layer on the side of the first reflective layer away from the substrate, and the plurality of electrical connection positions are provided on the circuit layer; and

electrically connecting the plurality of mini-light emitting diodes to each of the electrical connection positions, respectively.

Further, in the block of depositing the first reflective layer on the surface of the substrate to form the entire surface, the deposition is a physical vapor deposition process.

Further, the block of preparing the circuit layer on the side of the first reflective layer away from the substrate, and the plurality of electrical connection positions are provided on the circuit layer comprises following blocks of:

depositing a metal layer on the entire surface of the first reflective layer facing away from the substrate;

preparing a first photoresist layer forming an entire surface on a side of the metal layer facing away from the first reflective layer;

patterning the first photoresist layer to obtain a patterned first photoresist layer;

performing a patterning process on the metal layer, that is, removing metal in an area not covered by the patterned first photoresist layer to obtain a patterned metal layer; and

preparing the plurality of electrical connection positions on the patterned metal layer.

The present application provides a mini-light emitting diode light board. Compared with the existing mini-light emitting diode light board, the first reflective layer is added, and the first reflective layer is disposed between the substrate and the plurality of mini-light emitting diodes, in order to solve the existing problems of the existing mini-light emitting diode light board, wherein there is a gap between the edge of the white oil opening and the edge of the corresponding mini-light emitting diode, and light will leak from the gap, thereby reducing the utilization rate of light. In the mini-light emitting diode light board of the present application, the first reflective layer is provided in the gap to enhance the reflection effect of light, effectively preventing the leakage of light from the gap, thereby improving the utilization rate of light and greatly reducing the rate of light loss. The mini-light emitting diode light board can be used as the backlight source of the backlight module, which has the advantage of saving energy consumption.

### BRIEF DESCRIPTION OF DRAWINGS

FIG. 1 is a schematic structural diagram of a mini-LED light board in the prior art.

FIG. 2 is a schematic structural diagram of an embodiment of a mini-LED light board provided by the present application.

FIG. 3 is a schematic flow chart of an embodiment of a method for manufacturing a mini-LED light board provided by the present application.

FIG. 4 is a schematic flowchart of an embodiment of block S2 in FIG. 3.

FIG. 5 is a schematic flowchart of another embodiment of block S2 in FIG. 4.

FIG. 6 is a schematic cross-sectional view of an embodiment of a backlight module provided by the present application.

FIG. 7 is a schematic longitudinal cross-sectional view of an embodiment of the backlight module provided by the present application.

FIG. 8 is a schematic structural diagram of another embodiment of the backlight module provided by the present application.

FIG. 9 is a schematic flowchart of an embodiment of a method for manufacturing a backlight module provided by the present application.

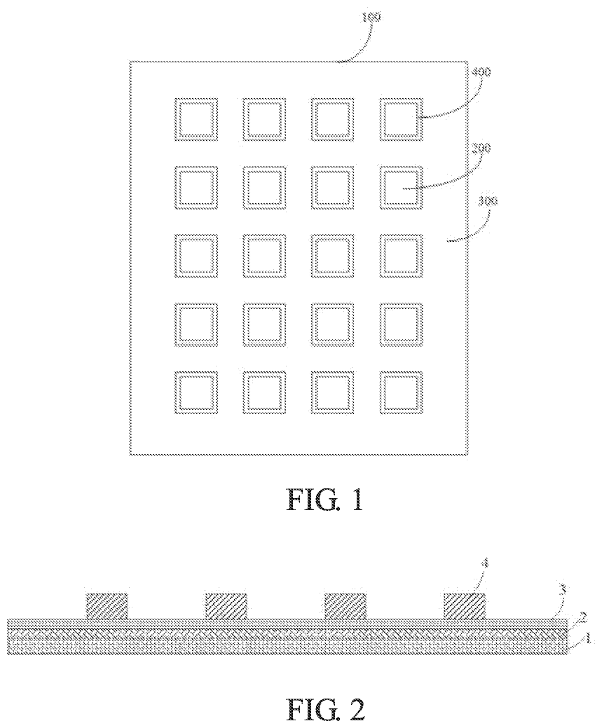

### DETAILED DESCRIPTION OF PREFERRED EMBODIMENTS

In order to make the above objectives, features, and advantages of the present invention more obvious and understandable, the preferred embodiments of the present invention are described in detail below in conjunction with the accompanying drawings. Furthermore, the directional terms mentioned in the present invention, such as “up”, “down”, “front”, “back”, “left”, “right”, “in”, “out”, “side”, etc., Only refer to the direction of the attached drawings. Therefore, the directional terms used are used to describe and understand the present invention, rather than to limit the present invention.

In a first aspect, as shown in FIG. 2, the present application provides a mini-light emitting diode (mini-LED) light board, mainly comprising: a substrate 1, a first reflective layer 2, a circuit layer 3, and a plurality of mini-LEDs 4. The first reflective layer 2 is laminated on a surface of the substrate 1, the circuit layer 3 is laminated on a surface of the first reflective layer 2 facing away from the substrate 1, and the plurality of mini-LEDs 4 are arranged on the circuit layer 3 at intervals.

The substrate 1 is configured to carry the plurality of mini-LEDs 4, and the material of the substrate 1 may be glass. In addition, the substrate 1 has a reflection effect on the light emitted by the mini-LEDs 4 to reduce the light loss rate.

The first reflection layer 2 is a distributed Bragg reflector structure, that is, a composite layer structure formed by alternately setting two material layers with different refractive indexes. The first reflective layer 2 can improve the utilization of light and enhance the reflection effect of light.

As a preferred embodiment, the first reflective layer 2 is composed of a first silicon nitride (SiNx) layer, a silicon oxide (SiOx) layer, and a second silicon nitride layer stacked in sequence.

As another preferred embodiment, the first reflective layer 2 is composed of a first silicon nitride (SiNx) layer, an amorphous silicon (a-Si) layer, and a second silicon nitride (SiNx) layer stacked in sequence.

It should be noted that the overall thickness of the first reflective layer 2 and the thickness of each material layer constituting the first reflective layer 2 are not specifically limited, and can be selected according to actual needs.

The circuit layer 3 is provided with a plurality of electrical connection positions, and each of the electrical connection positions comprises a positive electrode connection position and a negative electrode connection position. The circuit layer 3 may comprise a patterned metal layer, and the material of the metal layer may be a single metal such as molybdenum (Mo), aluminum (Al), copper (Cu), or titanium (Ti), or an alloy, In addition, the metal layer may have a single-layer structure or a multi-layer structure, and at least two layers of the multi-layer structure have different materials.

As a preferred embodiment, the circuit layer 3 may be a printed circuit board (PCB), a BT (Bismaleimide Triazine) board, an aluminum substrate, a flexible printed circuit (FPC) board, or other circuit board structures.

The plurality of mini-LEDs 4 are electrically connected to each of the electrical connection positions, that is, each of the mini-LEDs 4 is electrically connected to a positive electrode connection position and a negative electrode connection position. An external power source is electrically connected to each of the mini-LEDs 4 through the electrical connection positions, thereby providing light-emitting power for each of the mini-LEDs 4. The number of the plurality of mini-LEDs 4 is not specifically limited, and can be selected according to actual needs.

Those skilled in the art can understand that the mini-LED light board should also comprise some other necessary structural components to ensure the normal operation of the mini-LED light board, such as a glue layer.

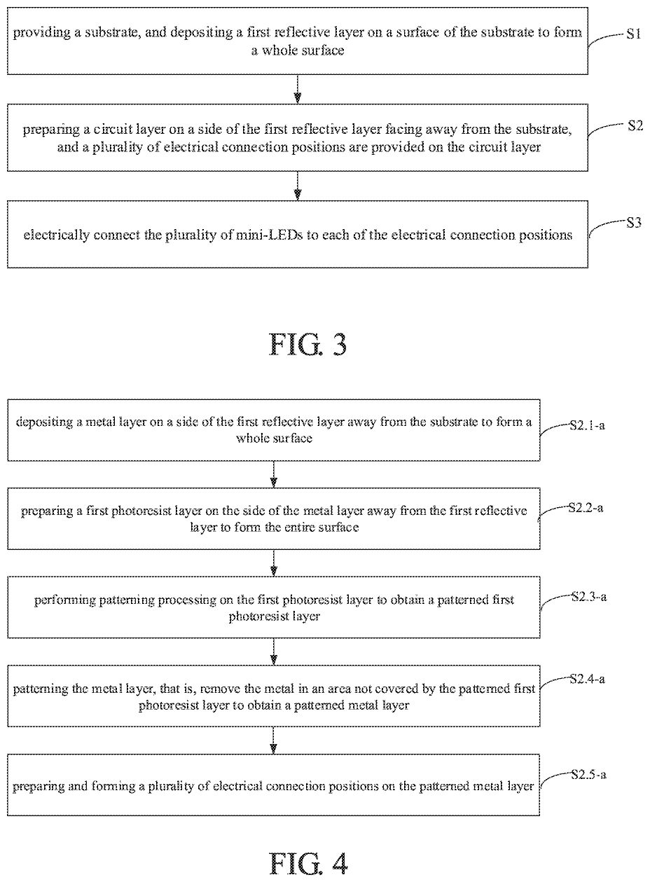

In a second aspect, the present application provides a method for manufacturing a mini-LED light board, which is used to manufacture the mini-LED light board described in the first aspect, as shown in FIG. 3, comprising following blocks of:

S1: providing a substrate, and depositing a first reflective layer on a surface of the substrate to form a whole surface.

S2: preparing a circuit layer on a side of the first reflective layer facing away from the substrate, and a plurality of electrical connection positions are provided on the circuit layer.

Specifically, the preparation of the circuit layer is a conventional technical means in the art. The circuit layer can be prepared directly on the first reflective layer by photolithography and etching processes, or ink-jet printing (IJP) process preparation to form the circuit layer; or, first prepare a circuit board structure separately, and then adhere the circuit board structure to the side of the first reflective layer facing away from the substrate through an adhesive.

In an embodiment, as shown in FIG. 4, the block of S2 comprises following blocks of:

S2.1-a: depositing a metal layer on a side of the first reflective layer away from the substrate to form a whole surface.

Specifically, a physical vapor deposition (PVD) process is used to deposit a metal layer on the entire surface on the first reflective layer, and the material of the metal layer is preferably copper (Cu).

S2.2-a: preparing a first photoresist layer on the side of the metal layer away from the first reflective layer to form the entire surface.

Specifically, a photoresist material is first coated on the side of the metal layer facing away from the first reflective layer, and then dried to form the first photoresist layer.

S2.3-a: performing patterning processing on the first photoresist layer to obtain a patterned first photoresist layer.

Specifically, the patterning process is a conventional technical means in the art, comprising processes such as exposure, development, and drying.

S2.4-a: patterning the metal layer, that is, remove the metal in an area not covered by the patterned first photoresist layer to obtain a patterned metal layer.

Specifically, the metal layer may be patterned by wet etching, that is, the metal in the area not covered by the patterned first photoresist layer is removed by etching with a chemical solution.

S2.5-a: preparing and forming a plurality of electrical connection positions on the patterned metal layer.

Specifically, first, the remaining first photoresist layer on the patterned metal layer is removed; then, a second photoresist layer is deposited on the patterned metal layer; finally, the first photoresist layer is deposited on the patterned metal layer. A plurality of electrical connection positions are etched on the second photoresist layer, and the etching method may be photoetching, die cutting, etc.

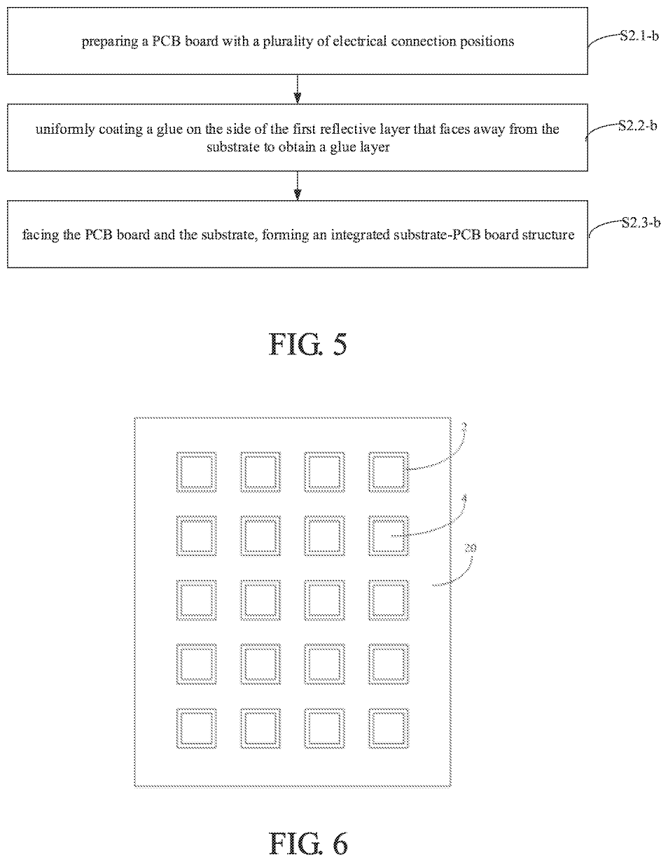

In another embodiment, as shown in FIG. 5, the block of S2 comprises:

S2.1-b: preparing a PCB board with a plurality of electrical connection positions.

S2.2-b: uniformly coating a glue on the side of the first reflective layer that faces away from the substrate to obtain a glue layer.

S2.3-b: facing the PCB board and the substrate, forming an integrated substrate-PCB board structure.

For blocks of S2.1-b to S2.3-b, it should be noted that the block of S2.1-b and the block of S2.2-b can be performed in an exchanged order, or can be performed simultaneously. In the block S2.1-b, the PCB board is prepared by conventional technical means in the art, which will not be repeated here. In the block S2.2-b, the glue is a glue with ideal light transmittance.

S3: electrically connect the plurality of mini-LEDs to each of the electrical connection positions.

Specifically, a plurality of mini-LEDs are electrically connected to each of the electrical connection positions through surface mounted technology (SMT).

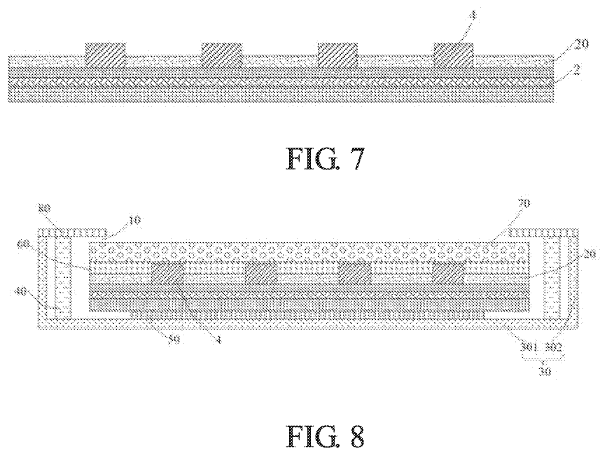

In a third aspect, the present application provides a backlight module, as shown in FIGS. 6 and 7, the backlight module comprises: the mini-LED light board described in the first aspect and a second reflective layer 20, and the second reflective layer 20 is laminated on a surface of the mini-LED light board.

The second reflective layer 20 is respectively provided with an opening at the position of each of the mini-LEDs 4 so that each of the mini-LEDs 4 is exposed. Due to the opening process, there is a gap between each of the openings and the edge of the corresponding mini-LED 4, but because the first reflective layer 2 with enhanced reflection effect is additionally provided, the light will not escape from the gap, thereby effectively improving the utilization of light.

In one embodiment, the material of the second reflective layer 20 is white ink with reflective effect. The thickness of the second reflective layer 20 is 5 micrometers to 10 micrometers, wherein each of the mini-LEDs 4 protrudes from the corresponding openings outside the upper surface of the second reflective layer 20, that is, in a longitudinal direction, the top of the second reflective layer 20 is not higher than the top of each of the mini-LEDs 4 to ensure that each of the mini-LEDs 4 has a high light extraction efficiency.

Those skilled in the art can understand that the backlight module may also comprise some other structural parts, such as: optical film set, protective layer, outer frame, plastic frame, glue layer, light-shielding layer, etc. These structural parts are necessary components that guarantee the normal operation of the backlight module, or have the function of improving certain aspects of the performance of the backlight module.

In an embodiment, as shown in FIG. 8, the backlight module mainly comprises: a mini-LED light board, a second reflective layer 20, an outer frame 30, a plastic frame 40, a double-sided adhesive layer 50, a protective layer 60, an optical film set 70, and a light shielding layer 80. Wherein, the outer frame 30 is formed by enclosing a metal back plate 301 and four metal retaining walls 302 (only two metal retaining walls 302 are shown in FIG. 8). The metal back plate 301, the double-sided adhesive layer 50, the mini-LED light board, the second reflective layer 20, the protective layer 60, and the optical film set 70 are stacked in sequence. The plastic frame 40 is arranged around the double-sided adhesive layer 50, the mini-LED light board, the protective layer 60, and the optical film set 70, and the plastic frame 40 is arranged on the metal back plate 301, each of the metal retaining walls 302 is respectively arranged on the periphery of the plastic frame 40. The light-shielding layer 80 is disposed on the top of each of the metal barrier walls 302 and extends above a part of the optical film set 70 to ensure that each of the mini-LEDs 4 is not blocked.

The outer frame 30 is a bearing of the overall structure of the backlight module, and is configured to support various components of the backlight module. The material of the outer frame 30 may be copper (Cu), aluminum (Al), alloy, or the like. The metal back plate 301 and the four metal retaining walls 302 may be an integrally formed structure, or may not be an integrally formed structure. The double-sided adhesive layer 50 is configured to adhere the mini-LED light board 10 to the metal back plate 301.

The structural composition of the mini-LED light board and the second reflective layer 20, and the relationship between the two are as described above, and will not be repeated here.

The protective layer 60 covers the plurality of mini-LEDs 4 and extends to the second reflective layer 20. The protective layer 60 is configured to encapsulate the plurality of mini-LEDs 4 to prevent the plurality of mini-LEDs 4 from falling off and getting damp. The material of the protective layer 60 may be silica gel, epoxy resin, or other colloidal materials with higher light transmittance.

The optical film set 70 may comprise one or more of a prism film, a quantum dot film, a diffuser, a reflective polarizer, etc., so that the backlight module can be adapted to various applications. For example, the prism sheet can change the exit angle of light, thereby changing the viewing angle of the display device. The quantum dot film can provide quantum dot light with higher monochromaticity, thereby broadening the display color gamut of the display device and greatly improving the display brightness. The reflective polarizer can improve the utilization of light, and at the same time make the emitted light polarized, so that the lower polarizer in the liquid crystal display panel can be omitted.

There is an air gap 10 between the light shielding layer 80 and the optical film set 70, that is, in a longitudinal direction, the top of each metal retaining wall 302 is higher than the top of the optical film set 70, so the function of the air gap 10 is to save deformation space for the optical film set 70, the mini-LED light board, and other components, so as to prevent the problem of deformation of the backlight module in a high temperature or low temperature environment.

In a fourth aspect, the present application provides a method for manufacturing a backlight module for manufacturing the backlight module described in the third aspect, comprising the blocks of: preparing a mini-LED light board; and printing a second reflective layer on a surface of the mini-LED light board, and the second reflective layer is respectively provided with an opening at the position of each mini-LED, so that each of the mini-LED is exposed.

Wherein, the preparation method of the mini-LED light board is described in the second aspect for details, and will not be repeated here. The second reflective layer can be prepared by printing methods such as jet printing, silk screen printing, and the like.

Those skilled in the art can understand that the preparation method of the backlight module also comprises the blocks of preparing some other structural parts. These structural parts are necessary components to ensure the normal operation of the backlight module, or have certain functions to improve the backlight module. The role of performance, for example: the preparation of optical film sets, protective layers, outer frames, plastic frames, adhesive layers, light-shielding layers, and other structural parts.

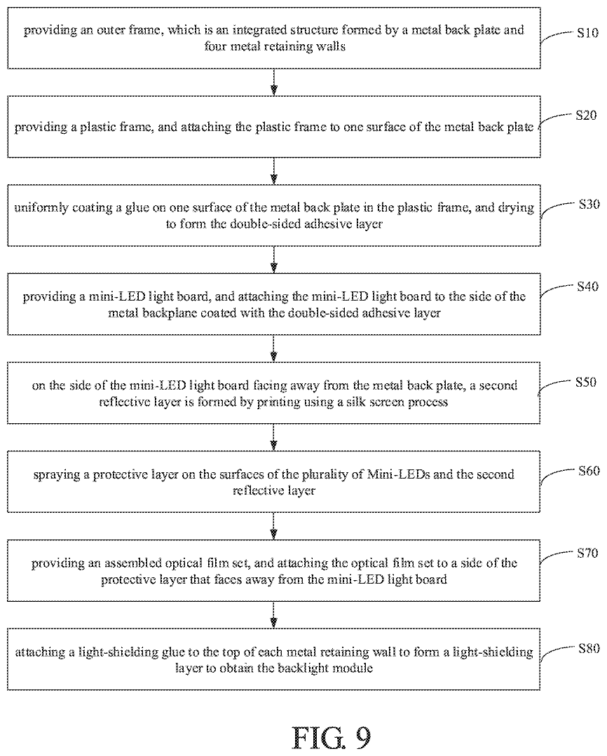

In one embodiment, a method for manufacturing a backlight module is provided for manufacturing the backlight module as shown in FIG. 8, as shown in FIG. 9, which specifically comprises the following blocks of:

S10: providing an outer frame, which is an integrated structure formed by a metal back plate and four metal retaining walls.

S20: providing a plastic frame, and attaching the plastic frame to one surface of the metal back plate.

S30: uniformly coating a glue on one surface of the metal back plate in the plastic frame, and drying to form the double-sided adhesive layer.

S40: providing a mini-LED light board, and attaching the mini-LED light board to the side of the metal backplane coated with the double-sided adhesive layer.

S50: on the side of the mini-LED light board facing away from the metal back plate, a second reflective layer is formed by printing using a silk screen process.

S60: spraying a protective layer on the surfaces of the plurality of mini-LEDs and the second reflective layer.

S70: providing an assembled optical film set, and attaching the optical film set to a side of the protective layer that faces away from the mini-LED light board.

S80: attaching a light-shielding glue to the top of each metal retaining wall to form a light-shielding layer to obtain the backlight module.

For the foregoing blocks, it should be noted that in the block of S10, the outer frame can be integrally formed by a mold, and the process parameters are not specifically limited, and can be selected according to actual needs. In the block of S40, the mini-LED light board is prepared with reference to the preparation method described in the second aspect. In the block of S70, the optical film set is assembled using conventional technical means in the art, which will not be repeated here.

In a fifth aspect, the embodiments of the present application provide a display device, which may be a mobile phone, a computer, a digital camera, a digital video camera, a game console, an audio reproduction device, an information terminal, a smart wearable device, and a smart weighing device. Any product or component with a display function, such as an electronic scale, a car display, a TV, etc., wherein the smart wearable device may be a smart bracelet, smart watch, smart glasses, etc.

The display device comprises: a backlight module as described in the third aspect and a display panel, and the display panel is located on the light emitting side of the backlight module. The backlight module can uniformly emit light in the entire light-emitting surface, and is configured to provide the display panel with light with reorganized brightness and uniform distribution so that the display panel can display images normally.

The display panel has a plurality of pixel units distributed in an array, and each pixel unit can independently control the transmittance and color of the light incident on the backlight module to modulate the light emitted by the backlight module, realizing image display. The display panel may be a product in the prior art, such as a liquid crystal display panel, a quantum dot display panel, and the like.

The present invention has been described in the above-mentioned related embodiments, but the above-mentioned embodiments are only examples for implementing the present invention. It must be pointed out that the disclosed embodiments do not limit the scope of the present invention. On the contrary, modifications and equivalent arrangements included in the spirit and scope of the claims are all included in the scope of the present invention.

What is claimed is:

1. A mini-light emitting diode light board, comprising:
a substrate;
a first reflective layer laminated on a surface of the substrate;
a circuit layer laminated on a surface of the first reflective layer facing away from the substrate, and a plurality of electrical connection positions are provided on the circuit layer; and
a plurality of mini-light emitting diodes electrically connected to each of the electrical connection positions, respectively, and the plurality of mini-light emitting diodes are arranged at intervals.

2. The mini-light emitting diode light board according to claim 1, wherein the first reflective layer is a distributed Bragg reflector structure.

3. The mini-light emitting diode light board according to claim 2, wherein the first reflective layer is composed of a first silicon nitride layer, a silicon oxide layer, and a second silicon nitride layer stacked in sequence.

4. The mini-light emitting diode light board according to claim 2, wherein the first reflective layer is composed of a first silicon nitride layer, an amorphous silicon layer, and a second silicon nitride layer stacked in sequence.

5. The mini-light emitting diode light board according to claim 1, wherein the circuit layer is at least one of a printed circuit board, a BT board, an aluminum substrate, or a flexible circuit board.

6. A backlight module, comprising:
a mini-light emitting diode light board, the mini-light emitting diode light board comprising: a substrate, a first reflective layer, a circuit layer, and a plurality of mini-light emitting diodes; the first reflective layer is laminated on a surface of the substrate, the circuit layer is laminated on a surface of the first reflective layer facing away from the substrate, a plurality of electrical connection positions are provided on the circuit layer, the plurality of mini-light emitting diodes are electrically connected to each of the electrical connection positions, respectively, and the plurality of mini-light emitting diodes are arranged at intervals; and
a second reflective layer laminated on a surface of the mini-light emitting diode light board, and a plurality of spaced openings are provided on the second reflective layer to expose each of the mini-light emitting diodes.

7. The backlight module according to claim 6, wherein a material of the second reflective layer is white ink with reflective effect.

8. The backlight module according to claim 6, wherein the backlight module further comprises: a protective layer covering each of the mini-light emitting diodes and the second reflective layer.

9. The backlight module according to claim 8, wherein a material of the protective layer is silica gel or epoxy resin.

10. The backlight module according to claim 6, wherein the backlight module further comprises: an optical film laminated on a surface of the second reflective layer facing away from the mini-light emitting diode light board.

11. The backlight module according to claim 10, wherein the optical film comprises one or more of a prism film, a quantum dot film, a diffusion film, and a reflective polarizer.

12. The backlight module according to claim 6, wherein the backlight module further comprises: an outer frame, the outer frame is composed of a metal back plate and four metal retaining walls, the metal back plate, the micro light emitting diode light board and the second reflective layer are laminated and arranged in sequence, and each of the metal retaining walls is arranged around the micro light emitting diode light board and the second reflective layer.

13. The backlight module according to claim 12, wherein the backlight module further comprises: a plastic frame arranged around the mini-light emitting diode light board and the second reflective layer, and each of the metal retaining walls is respectively arranged on a periphery of the plastic frame.

14. The backlight module according to claim 12, wherein the backlight module further comprises: a double-sided adhesive layer disposed between the metal back plate and the mini-light emitting diode light board.

15. The backlight module according to claim 12, wherein the backlight module further comprises: a light-shielding layer disposed on a top of each of the metal retaining walls.

16. A method for manufacturing a backlight module, comprising following blocks of:
preparing a mini-light emitting diode light board, wherein the mini-light emitting diode light board comprises: a substrate; a first reflective layer laminated on a surface of the substrate; a circuit layer laminated on a surface of the first reflective layer facing away from the substrate; and a plurality of electrical connection positions provided on the circuit layer; and a plurality of mini-light emitting diodes are electrically connected to each of the electrical connection positions, respectively, and the plurality of mini-light emitting diodes are arranged at intervals; and
printing a second reflective layer on a surface of the mini-light emitting diode light board, and the second reflective layer is respectively provided with an opening at a position of each of the mini-light emitting diodes, so that each of the mini-light emitting diodes is exposed.

17. The method for manufacturing the backlight module according to claim 16, wherein in the block of printing the second reflective layer on the surface of the mini-light emitting diode light board, the printing is a jet printing process or a silk screen process.

18. The method for manufacturing the backlight module according to claim 16, wherein the block of preparing the mini-light emitting diode light board comprises following blocks of:
providing the substrate, and depositing the first reflective layer on the surface of the substrate to form an entire surface;
preparing the circuit layer on the side of the first reflective layer away from the substrate, and the plurality of electrical connection positions are provided on the circuit layer; and
electrically connecting the plurality of mini-light emitting diodes to each of the electrical connection positions, respectively.

19. The method for manufacturing the backlight module according to claim 18, wherein in the block of depositing the first reflective layer on the surface of the substrate to form the entire surface, the deposition is a physical vapor deposition process.

20. The method for manufacturing the backlight module according to claim 18, wherein the block of preparing the circuit layer on the side of the first reflective layer away from the substrate, and the plurality of electrical connection positions are provided on the circuit layer comprises following blocks of:
depositing a metal layer on the entire surface of the first reflective layer facing away from the substrate;
preparing a first photoresist layer forming an entire surface on a side of the metal layer facing away from the first reflective layer;
patterning the first photoresist layer to obtain a patterned first photoresist layer;
performing a patterning process on the metal layer, that is, removing metal in an area not covered by the patterned first photoresist layer to obtain a patterned metal layer; and
preparing the plurality of electrical connection positions on the patterned metal layer.
